(19) United States
(12) Patent Application Publication
(10) Pub. No.: US 2011/0089949 A1
(43) Pub. Date: Apr. 21, 2011

(54) Parallel Imaging Apparatus and Method

(76) Inventor: Walid KYRIAKOS, Brookline, MA (US)

(21) Appl. No.: 12/897,577

(22) Filed: Oct. 4, 2010

Related U.S. Application Data
(60) Provisional application No. 61/248,252, filed on Oct. 2, 2009.

(51) Int. Cl. G01R 33/44

(52) U.S. Cl. 324/322

(57) ABSTRACT

A parallel MRI method and apparatus are provided. In some aspects the individual coils of the imaging array are designed to have optimized shapes and/or sizes to suit an imaging purpose. For example, varying coil sizes depending on an imaging effectiveness into a region or interest, including by combining more than one element of the array to form a virtual or combined element is used to reduce the computational requirements for parallel imaging.

### RELATED APPLICATIONS

This application claims the priority and benefit, under 35 USC §119(e), of provisional patent application Ser. No. 61/248,252, filed on Oct. 2, 2009, bearing the same title.

### TECHNICAL FIELD

The present disclosure relates to nuclear magnetic resonance (NMR) or magnetic resonance imaging (MRI). And in particular, it relates to imaging with multiple imaging coils in the context of parallel MRI.

### BACKGROUND

The basic operation of magnetic resonance imaging (MRI) and nuclear magnetic resonance (NMR) systems will not be fully explained here, but can be learned from the literature known to those skilled in the art. Furthermore, the concept of parallel imaging in the context of MRI, using multiple RF receiver coils is known in the present field, and will not itself be explained in detail. However, those concerned with the clinical use of MRI systems and those working to develop better MRI systems and techniques would appreciate that quality, resolution, and the pursuit of low-noise images in real time or in an expeditious manner is desirable. Also, that reducing the computational and imaging hardware resources to achieve such rapid high quality imaging is a desired goal.

Hardy et al. (Magn. Reson. Med., 55:1142-1149, 2006), which is hereby referenced and incorporated by reference, showed that smaller elements on the anterior side of the torso, and larger elements on the posterior side produced better g-factor maps at the heart, as compared to similarly sized elements on both sides thereof. This research would indicate that improved imaging can be obtained using smaller coil arrays in the vicinity of the ROI, which would improve SNR and large intensity variations in the ROI, and also contribute most of the spatial encoding; while larger elements further away from the ROI would provide the ability to collect a meaningful signal contribution rather than noise from the ROI, and primarily assist in improving the SNR but not so much the spatial encoding of the system.

The state of the present art remains devoid of a good understanding of the effects of coil shape and size, and hence improvements to parallel MRI imaging have been limited by limitations in this understanding and a lack of design refinements related to these aspects. While massively parallel (many-coil) imaging provides useful signal-to-noise ratio (SNR) improvements near the coil surfaces, the advantages in SNR deeper within the imaged structure or sample are more elusive. The present disclosure describes certain methods and apparatus for MRI using parallel imaging to obtain improved quality images using fewer resources and/or in a faster time.

### SUMMARY

In various embodiments, the present disclosure is directed to optimization of coil design (e.g., shape, size) in the context of multi-coil systems used in parallel magnetic resonance imaging (MRI). Aspects hereof minimize the number of required coils in a multi-coil array without substantially adversely affecting the quality of the resulting images. This can result in faster reconstruction times, less processing resource requirements, less data storage requirements, faster information transfer rates, and improved images from computationally intensive applications such as 3D and real-time applications.

The optimization of the number and shape of the coil elements in an array can also be performed using finite element modeling or similar techniques whereby a large number of elementary elements forming a baseline coil array, and placed on a surface around a field of view (FOV), can be evolved to a lower number of elements while still maintaining a set of preferred conditions or cost functions.

Some present embodiments are directed to a method for imaging of a region of interest (ROI) within a field of view (FOV) of a multiple-sensor imaging array, comprising placing at least a portion of an object to be imaged within said field of view (FOV) of said array such that the region of interest (ROI) spatially includes at least a portion of said object, determining a first subset of sensors of said multiple-sensor array that are to be combined into a first virtual sensor, determining a second subset of sensors of said multiple-sensor array that are to be combined into a second virtual sensor, and reconstructing an image of said object in said FOV from at least said first and second virtual sensors where a total number of virtual sensors used in said reconstructing is less than a total number of sensors in said multi-sensor imaging array.

Other embodiments are directed to an apparatus for parallel imaging comprising a plurality of individual sensors each susceptible to a signal emitted from an object in a region of interest of said apparatus, a first subset of said plurality of individual sensors combined to provide a first combined output signal, and a second subset of said plurality of individual sensors combined to provide a second combined output signal, and a processor receiving said first and second combined output signals from said first and second subsets of sensors and providing an output of said processor representative of an image of said object.

Yet other embodiments are directed to a parallel imaging apparatus comprising a plurality of individual imaging coils arranged in an array and disposed in space with respect to a field of view of said apparatus, at least one individual imaging coil being relatively preferentially disposed with respect to a region of interest within said field of view, at least one individual imaging coil being relatively non-preferentially disposed with respect to a region of interest within said field of view, a first combined group of imaging coils including said first individual imaging coil, said first combined group being spatially responsive substantially in a first region within said field of view, a second combined group of imaging coils including said second individual imaging coil, said second combined group being spatially responsive substantially in a second region within said field of view, said second region being greater in spatial extent than said first region, and a processor receiving a first signal from said first group of imaging coils representative of a combined output of the first combined group of imaging coils and receiving a second signal from said second group of imaging coils representative of a combined output of the second combined group of imaging coils, and providing an output based at least on said first and second signals representative of an image of an object in said region of interest.

### BRIEF DESCRIPTION OF THE DRAWINGS

For a fuller understanding of the nature and advantages of the present concepts, reference is be made to the following detailed description of preferred embodiments and in connection with the accompanying drawings, in which:

FIG. 1 illustrates an exemplary MRI apparatus;

FIG. 2 illustrates exemplary multi-coil imaging components of an MRI apparatus;

FIG. 3 illustrates the effect of grouping several individual coils into respective combined coil groups performing parallel imaging of the heart in a region of interest;

FIG. 4 illustrates exemplary images obtained by successively combining and accelerating an image obtained from parallel MRI imaging of the heart using various numbers of combined coils; and

FIG. 5 illustrates an exemplary plot of SNR and artifact power within the ROI.

### DETAILED DESCRIPTION

Parallel imaging uses a plurality of radio frequency (RF) receiver coils to encode received signals indicative of a condition of a sample within a region of interest (ROI). Information received by the RF receiver coils is processed to form images to display the condition of the sample in the ROI to an observer of the images. The images are for example displayed on a display screen, monitor, printer, or saved as static or animated files in some data storage medium.

In parallel imaging a spatial sensitivity profile is associated with each of the plurality of the RF receiver coils, and the spatial sensitivity profiles are used along with phase encoding to obtain imaging benefits and accelerations in speed and to reduce folding artifacts.

Present parallel imaging systems use multiple identical or same-shaped coil elements to perform the MRI, and as resources permit, more and more such similar coils are used to derive further parallelization of the MRI images and imaging methods. This however comes at a cost in that these systems require more and more computational resources and overload the capabilities of the processing system coupled to the receiver coil systems. Also, impractical image reconstruction times become needed as the resulting data and computational complexity from such many-coil systems increases.

Moreover, the enhancement of the resulting images and increase in the speed of imaging in parallel MRI systems is not proportional to the number of RF receiver coils used. Therefore, using more and more receiver coils is not as efficient or even as effective as one would hope in view of the complexity and cost of adding such numbers of coils.

One cause for the above issues is that the physics of electromagnetic fields, and the design of the receiver coils. Receiver coil sensitivity functions are generally limited to smooth functions in space. Some determinants of the effectiveness of a coil array are the spatial sensitivity profiles and the B1 field penetration of individual elements thereof. These are in turn a function of coil size, shape and location with respect to the ROI.

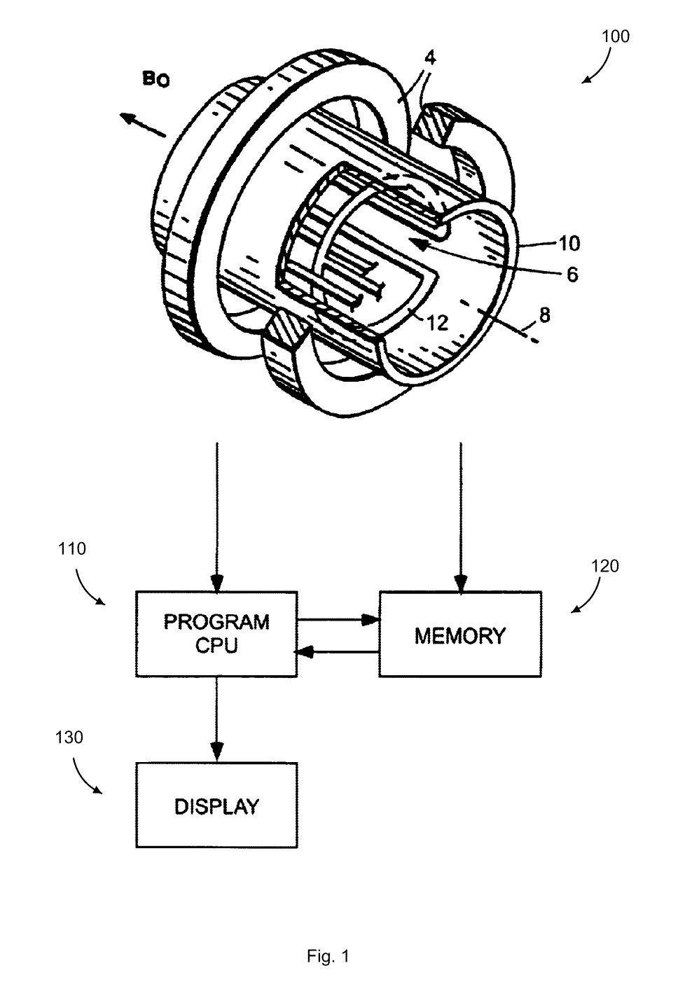

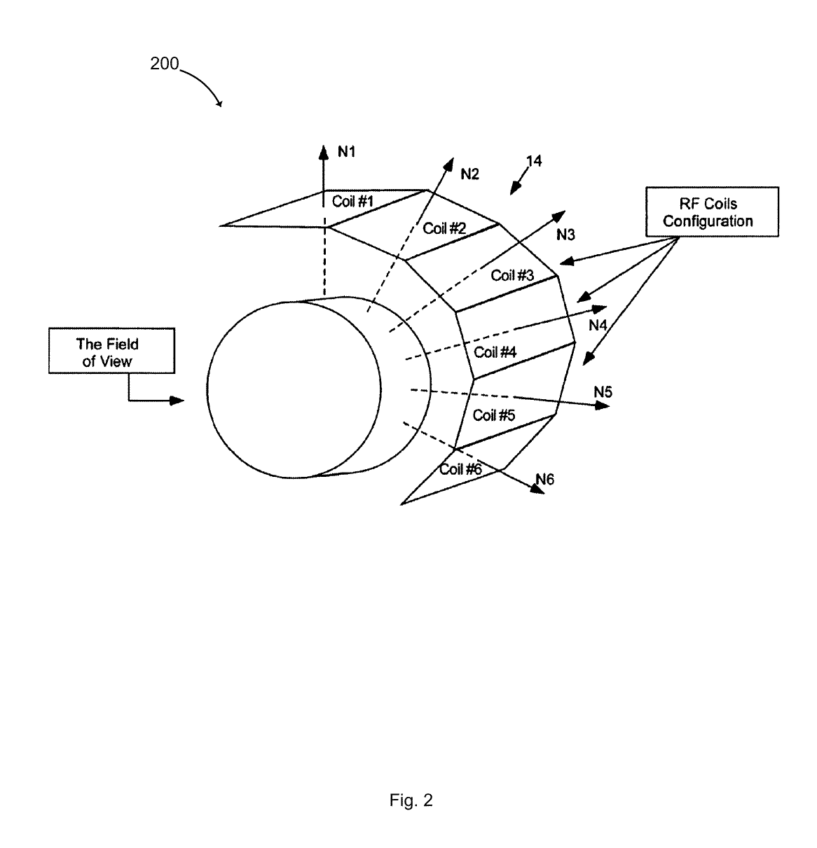

Referring now to the drawings, and particularly to FIGS. 1 and 2, it will be seen that the present invention provides a magnetic resonance imaging system. The system includes a plurality of gradient coils that produce spatially encoded gradients imposed upon a background magnetic field B.sub.o (where the notation “sub” denotes a “subscript” expression) within a volume in which an object of interest (e.g., a patient, an organ) to be examined is placed. The object being imaged is generally located at or in or proximal to a field of view (FOV). In addition, an array of RF receiver coils is disposed in an arrangement about (for example, circumferentially spaced) or in relation to one another about the imaging volume.

More specifically, the magnetic resonance imaging system, generally indicated at 100 in FIG. 1, may include a Helmholtz coil pair 4 used to generate a large, static, substantially homogeneous magnetic field in the imaging space or volume 6 in a direction parallel to the field's axis, sometimes referred to as the z-axis (in this embodiment coinciding with the line 8). An object or subject (not shown) may be placed in the imaging volume within the cylinder 10 for examination using NMR phenomena. The subject is placed on or near the z-axis or the line 8, and is at least partially located within the coil 12. The coil 12 is representative of devices used to generate radio frequency (RF) fields in the subject placed in the system for examination. The sensitivity of the individual sensors (e.g. pickup coils) in a multi-sensor (e.g. multi-coil) array depends on a number of factors, including physical design factors relating to the elements of the array and their configuration within the array. It should be appreciated that the present discussion may be applied where appropriate to closed bore, open bore, narrow bore and wide bore magnet systems.

The above RF fields, when in the presence of a static magnetic field B.sub.o, cause the occurrence of magnetic resonance in the nuclei of certain elements, such as hydrogen, in the specimen to be examined. These allow sensing and then reconstruction of a MRI image that can be stored, transmitted, or displayed for analysis, diagnosis, or other purposes. Many post-processing and image refinement processes may be brought to bear to create and improve or enhance a MRI image, some depending on the nature of and application at hand. Examples of such processing and reconstruction are given in the literature in this field and earlier patents by the present inventors, referred to herein and incorporated by reference. Such processing can occur in part in a computer workstation that is part of the MRI system such as a program CPU 110, which is coupled to a memory storage apparatus 120 and optionally to a display unit 130.

The direction of the static magnetic field (B.sub.o) produced by the coil pair 4 is indicated in FIG. 1 by an arrow near the left of the drawing. Currents are made to flow in the RF coil 12. In general, the direction of the currents reverse each half-cycle of the alternating RF current in coil 12. This produces a transverse magnetic field of low magnitude compared to B.sub.o. The magnitude of the flux density resulting from the static magnetic-field intensity B.sub.o may be typically on the order of a Tesla for clinical imaging applications.

The static magnetic field B.sub.o is constant while the subject is in the system for analysis or examination. The RF transverse magnetic field is applied for a time sufficient to allow the protons in the hydrogen atoms (or the nuclei of other atoms exhibiting the magnetic resonance phenomenon) to be affected such that precession of the net magnetization of the subject occurs. The precision of the net magnetic field associated with the nuclei in the subject occurs at the Larmor frequency, which is directly proportional to the magnitude of the magnetic field at the location of the nuclei. This can be detected as a nuclear magnetic resonance (NMR) signal, which provides information for the reconstruction and generation of an image of the object under examination.

In MRI systems, various gradient coils (not shown) are employed for producing spatially encoding gradients that are imposed upon the static magnetic field within the region in which the subject to be examined is placed also are provided. The gradient-coil apparatus is typically positioned on the outside of a cylindrical surface, such as the surface 10, which may be used as a support structure for the gradient coils. The gradient coils typically produce linear magnetic field gradients in any of the three orthogonal directions x, y and z. As mentioned above, the direction of the line 8 is designated as the z-direction or z-axis and the x- and y-axes of the coordinate system are orthogonal to the z-axis and to one another.

A typical configuration of a z-gradient coil is illustrated in U.S. Pat. No. 4,468,622, the disclosure of which is hereby incorporated by reference. The configuration of the typical transverse (x or y) gradient coils is illustrated in U.S. Pat. No. 4,486,711, the disclosure of which is also hereby incorporated by reference.

With reference to FIG. 1, the system also includes a central processor 20 which can be a central processing unit (CPU), a memory device 30, and a display device 40. Variations of such systems are described in U.S. Pat. No. 6,680,610, co-invented by the present inventor, which is hereby incorporated by reference in its entirety, along with any citations to prior art referred to therein. Other auxiliary and supporting systems are often coupled to the MRI system as known to those skilled in the art or as would be reasonable for a given implementation of the system. For example, the system may be coupled to a data network for moving data such as files, images, and so on between the system and other systems connected to the network.

Now referring to FIG. 2, the present system and method also contemplates that an array of RF receiver coils 14 will surround (or partially surround) the imaging volume. FIG. 2 illustrates a schematic representation in 3-D of the field of view (FOV) and the RF pickup coil array positioning in an embodiment hereof. The coil orientations are described by vectors orthogonal to the coils. These RF receiver coils 14 provide the required system calibration and input information necessary to enhance the speed of parallel magnetic resonance data acquisition and parallel image reconstruction, without serious adverse effect upon acceptable signal-to-noise (SNR) ratios. The present embodiments employ multiple receiver coils, with each coil providing some information about the image.

In some embodiments hereof, the present disclosure provides a way to reduce the size of the imaging array without loss of image quality and without loss in acceleration speed of imaging by linearly combining subsets of small coils into larger coil elements, where these elements can have differing sizes (and/or shapes).

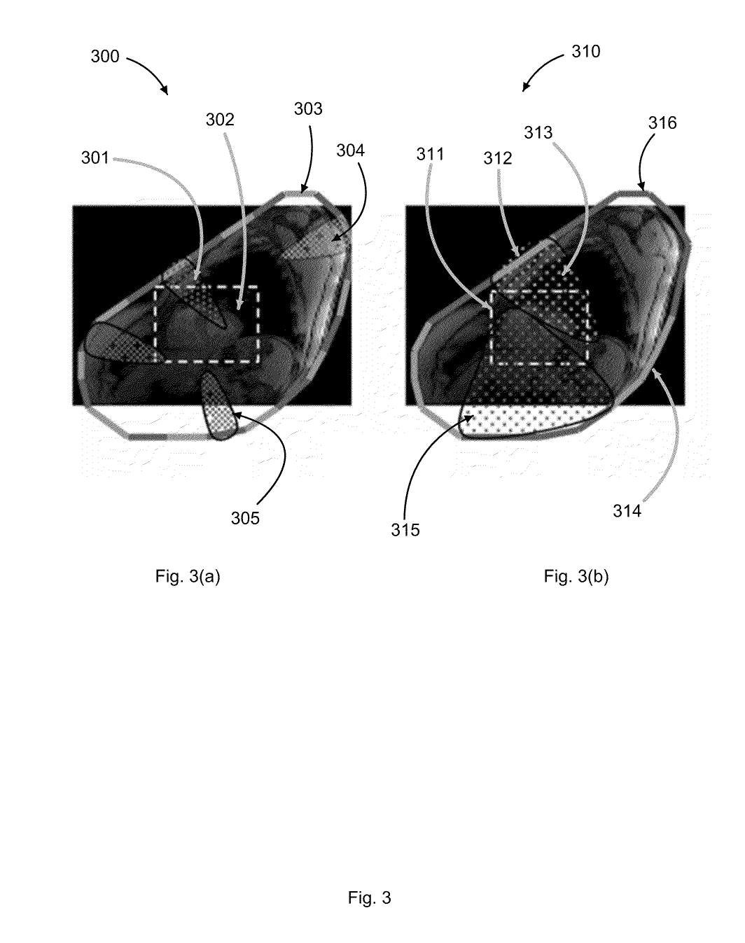

Now referring to FIG. 3, according to some preferred embodiments, a two-dimensional (2D) cardiac image data set can be used for illustrative purposes. This data set may be for example acquired using a multi-coil (e.g., 16-, 32, 64, or 128-coil) array. FIGS. 3(a) and 3(b) illustrate an example of how the present apparatus and method can benefit the imaging of an object or organ of a patient within a field of view (FOV).

FIG. 3(a) illustrates a sum of squares image from all of the coil elements as well as a schematic representation of the individual coils (drawn as segments) surrounding the FOV, to graphically convey the present principles. The effective penetration ability of four exemplary coils to provide imaging data in the FOV is shown in the dotted regions adjacent to their respective coil elements.

As shown in FIG. 3(a), the elements 303 of a multi-coil array are usually identical or generally have the same or similar sizes and shapes and are distributed around a FOV. Within the FOV one is most interested in a region of interest (ROI) 302 shown by the white dashed rectangle near the center of the FOV. In this example the ROI is directed to the heart of a patient by a 2D cardiac image taken along the long axis view of the imager. The dotted regions (e.g., 301, 304, 305) are meant to represent spatial regions within the FOV which the corresponding coil element is providing imaging information to a certain effective depth and spatial extent into the FOV. Note how some coil elements do not effectively provide a penetration depth or sensitivity extending into the ROI 302. For these coil elements the penetration depth from which they can collect effective information (e.g., in region 304) this information provides little or no assistance in imaging the heart, located in ROI 302. One reason is the distance of the coil element to the right of FIG. 3(a) and the size of the element, making region 304 not penetrate into ROI 302. Accordingly, if a traditional parallel MRI apparatus were to collect, store, and process data from each of the multiple elements shown in FIG. 3(a), much of this data and processing is not useful or effective for making a high quality MRI image of the heart in ROI 302. In fact, this information from distant regions 304 is similar to noise as far as an investigation of the ROI is concerned.

FIG. 3(b) now shows the same cardiac exemplary image 310, with the same coils of FIG. 3(a) combined to effectively form larger elements, where the size of the elements closest to the ROI 311 is small compared to the elements further from the ROI. The method of combining the coils is discussed further below. The result is that the elements in FIG. 3(b) have a lobe pattern or penetration region, e.g., that has sufficient SNR within the ROI 311 so as to provide reliable magnitude and phase information from the ROI. The penetration or sensitivity regions 313, 315 of two such elements is shown schematically as a representative with the dotted areas, each of which has a significant penetration into ROI 311.

The above example illustrate the present principle of combining a plurality of coil elements in a multi-element array to minimize the size of the array and yet to achieve an improved, even optimal, coil efficiency and configuration for acceleration of imaging of the ROI. The SENSE technique can be used in some embodiments to compute the accelerated images, but other techniques applied to the present coil designs or combined element designs can be used.

In the above example, one or more elements (coils) from the typical equal-element design of FIG. 3(a) are combined to make each of the elements of FIG. 3(b). That is, as shown in FIG. 3(b), the elements according to some aspects hereof do not need to be of the same size or shape. Rather, the individual imaging array of FIG. 3(b) comprises several coil elements, some having a larger size than others. For example, as shown, element 312 is smaller than element 314 or 316. Since element 316 is distant from the ROI 311 it is made larger in spatial extent and depth of penetration into the FOV than element 312 which is smaller in spatial extent and penetration. In this way, each of the elements of the array in FIG. 3(b) provides some useful penetration and sensitivity within the ROI 311 and not just within the FOV. Also, by combining elements of the multi-element array in FIG. 3(a) the system of FIG. 3(b) can accomplish comparable imaging results in a fraction of the time needed to carry out the computations from FIG. 3(a) on the same ROI and using a fraction of the computational and data processing and storage (memory) requirements. The efficiency of this technique will be further discussed below in an illustrative example.

As to implementation, the present techniques may be provided in the form of hardware, software, or both. Specifically, some present embodiments rely on physically designing, sizing, and shaping imaging coils to fit an application at hand. For example, in imaging an organ in a ROI in a patient's abdomen, rather than relying on equally sized and shaped and spaced elements disposed about the abdomen of the patient, the present method and system may place smaller elements close to the ROI and larger elements further from the ROI as alluded to in the reference above. And importantly, the present method and system can be used to combine or collect cumulative inputs from a plurality of imaging coil elements together so as to effectively form a single “combined” or “cumulative” or “aggregated” coil element (Ref. FIG. 3(b)). So if several small coils, none of which would have a useful penetrating ability to image into the ROI are found far from the ROI (like in region 304 of FIG. 3(a)) they can be combined or aggregated with some neighboring elements so that they collectively form a combined element (like element 316 in FIG. 3(b)) which does have a useful penetrating effect in the ROI. This may be performed in software by collectively combining the signals from a plurality of individual smaller coils to create a virtual larger combined coil (316). Using a combination of hardware design to variously size and form the coils as well as software combination of the coils is also possible in some embodiments.

It can be appreciated that when the number of coils is reduced by physically sizing and placing the appropriate lesser number of coils about the FOV that significant hardware as well as software and other savings are possible. The number of coils in the imaging array being reduced leads to fewer coil processing circuitry being required and the subsequent imaging calculations, storage needs, data transmission bandwidth and so on all being conserved. As to situations where many small (and perhaps conventional arrays of similar) coils are in the array, the software or programming technique for combining the signals from several coils into one virtual coil where appropriate yields fewer data storage and computational and data transmission bandwidth needs as well.

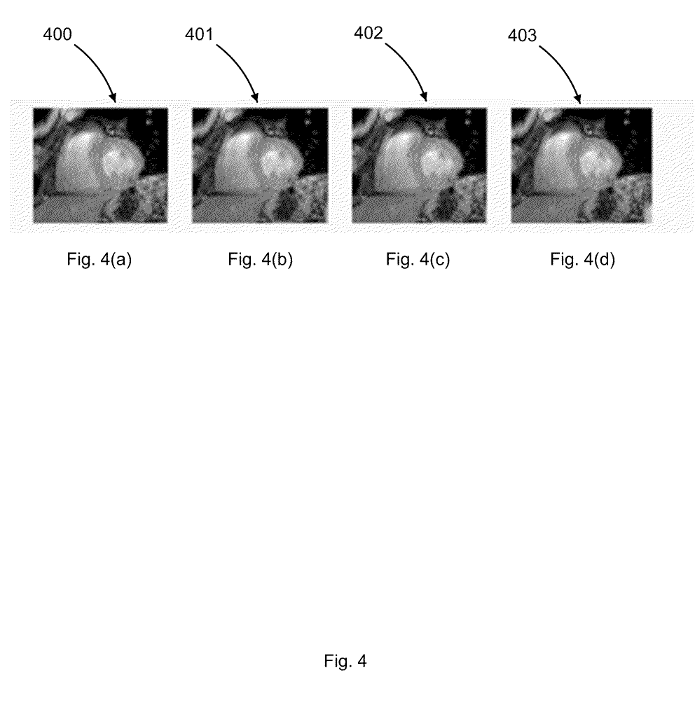

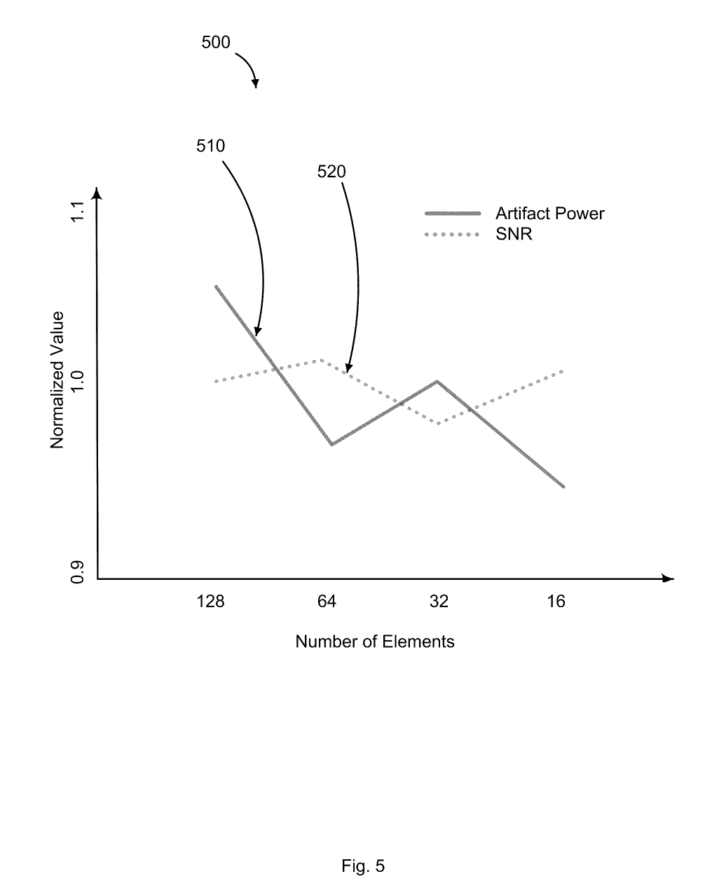

Some aspects hereof are directed to a method for optimizing the number, size and/or shape of the elements of an array to suit a particular imaging need. For example, finite element or other numerical methods can be used to determine in an automated fashion the optimal number and size of the coils of an array to use for imaging a given ROI in a FOV. Alternatively, or in conjunction therewith, an automated calculation can be used to determine an optimum way of combining existing smaller elements of an array into respective virtual or combined elements of the optimized and simplified array. These would yield faster and more efficient parallel MRI images, and also, would yield comparable quality images with less computing requirements as will be discussed below with reference to FIGS. 4 and 5.

In one aspect, an image acceleration factor was increased until aliasing artifacts became apparent in the ROI. The highest accelerated image, which is free from visible artifacts was then chosen as a reference image. It should be understood that the order of the steps and the intervening processing and optimization steps can be modified or adjusted to suit a particular need at hand by those skilled in the art. Also, the SENSE technique is to be understood as exemplary in the present discussion, and not limiting.

Referring to FIG. 4, several images are produced using virtual or combined array elements that are combined as described above to form effective imaging arrays of e.g. 16, 32, and 64 elements. These are exemplary for the purpose of illustration and are not intended to limit the present system or method. Some embodiments accomplish this by ensuring that all of the elements of the formed array maintain an intensity within a given region (e.g., in the ROI) that meets a criterion or is above some threshold value.

In some embodiments, the criterion or minimum threshold value corresponds to a sum of minimum signals from all of the (e.g., 128) coils within the ROI, divided by the number of coils in the reduced or combined formed array. Once the new coil combinations are determined, new data sets are computed for the combined elements, and SENSE (or another suitable technique) accelerated reconstructions are computed for the highest acceptable acceleration found for the initial data set. Then, the reconstructed images are compared for SNR (or another criterion) and artifact power to the reference image computed from the multiple (e.g., 128) coil array within the ROI.

In one exemplary embodiment, a 5-fold maximum acceleration of a artifact-free 2D image was obtained. Of course, the exact benefits are determined by many factors relating to the hardware, coils, ROI, and processing in general. The present exemplary embodiment is shown in FIG. 4(a), with reconstructions of the 5-fold accelerated images using 64, 32, and 16-element arrays shown in FIGS. 4(b)-4(d) respectively. Little or no visual difference can be found in images 400-403.

FIG. 5 illustrates a plot 500 of an exemplary SNR 520 and a determined artifact power 510 within a ROI for the coil configurations in the above exemplary embodiment of FIG. 4. Image reconstruction times in this exemplary embodiment were computed on an Apple Macintosh® computer from Apple, Inc. (Cupertino, Calif.) having a 2.2 GHz clock speed using MATLAB® from MathWorks, Inc. (Natick, Mass.). The image reconstruction times for the 128, 64, 32, and 16 element examples were found to be 6247 sec, 780 sec, 92 sec, and 8 sec, respectively. It should be appreciated that the present examples are merely illustrative, and those skilled in the art would understand the generalization of the instant examples to other software, hardware, and detailed implementations.

The discussion and examples above are meant to illustrate the use of an apparatus and method for parallel MRI imaging. However, where sensor arrays generally may be used the present systems and methods apply, even if outside the specific imaging modality of MRI. For example, if another modality is desired, then the above discussion is generalized to sensors sensing respective emissions from the objects in the regions of interest of those imagers.

The present apparatus and method may be implemented on a workstation or computer product having a processor, data communication, and/or data and instruction storage means such as is understood by those skilled in the art. Also, a monitor or analog or digital display device may be coupled to the system for display of the resulting images. The processor can be used to compute various values and take inputs and provide outputs from and to the rest of the system. Coupling such a system to a patient handling apparatus such as is used in known MRI systems is also comprehended by the present inventor.

In some or all embodiments, the present system and method result in cheaper, faster, more efficient, or better MRI images, or all of the above. Especially, the present system and method can provide equal or better imaging in the context of parallel imaging while using smaller or fewer RF receiver coils. The combinations of coils can be done in a fixed or in a custom pre-computed way to suit a given imaging need or patient. Image planning can accompany the present technique to best determine the actual specific coil combinations to be used. Also, determination of the proper or optimum size, number, and location of individual or combined coils is to be performed in some embodiments.

In some or all embodiments, an acceleration and/or efficiency and/or improved SNR can be obtained. The present method and system can bring out the best in coil design and processing optimization for parallel MRI systems. The number of coil elements or effective coil elements can be reduced or minimized accordingly, and a corresponding reduction in the need for computing resources is allowed. In some embodiments this effectively translates into using fewer coil elements to achieve the same or better imaging in the same or shorter time compared to many-coil or massively-parallel MRI systems. In some embodiments, this avoids data congestion and overload, and provides better reconstruction results in real time or near real time.

In some embodiments, the present systems and methods are useful for cardiac MRI imaging, but are not limited to this example. Also, coil design for coils not immediately in proximity with the ROI is improved.

The present system and methods also comprehend optimization of the designs discussed above taking into account the Ohmic noise and subject noise considerations in the coil and array designs.

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications and equivalents.

What is claimed is:

1. A method for imaging of a region of interest (ROI) within a field of view (FOV) of a multiple-sensor imaging array, comprising:
placing at least a portion of an object to be imaged within said field of view (FOV) of said array such that the region of interest (ROI) spatially includes at least a portion of said object;
determining a first subset of sensors of said multiple-sensor array that are to be combined into a first virtual sensor;
determining a second subset of sensors of said multiple-sensor array that are to be combined into a second virtual sensor; and
reconstructing an image of said object in said FOV from at least said first and second virtual sensors where a total number of virtual sensors used in said reconstructing is less than a total number of sensors in said multi-sensor imaging array.

2. The method of claim 1, said steps involving said sensors and multi-sensor array comprising steps in electromagnetic coils and corresponding coil multi-coil array.

3. The method of claim 1, said determining of the first and second subsets of sensors comprising respective determination of effective imaging contributions from the corresponding sensors of the multi-sensor array.

4. The method of claim 1, said determining steps further comprising respective grouping of more than one individual sensor element with other sensor elements proximal thereto to form said respective combined virtual sensors each of which includes the respective groupings of individual elements into the corresponding virtual sensor.

5. The method of claim 1, further comprising repetitively combining selected individual sensor elements so as to arrive at a smaller number of combined virtual elements from which an image of the object in the ROI may be reconstructed.

6. The method of claim 1, said determining steps including formation of combined virtual sensors that are larger in spatial extent where distant from the ROI and smaller in spatial extent where proximal to said ROI.

7. A parallel imaging apparatus, comprising:
a plurality of individual sensors each susceptible to a signal emitted from an object in a region of interest of said apparatus;
a first subset of said plurality of individual sensors combined to provide a first combined output signal, and a second subset of said plurality of individual sensors combined to provide a second combined output signal; and
a processor receiving said first and second combined output signals from said first and second subsets of sensors and providing an output of said processor representative of an image of said object.

8. The apparatus of claim 7, further comprising circuitry and instructions that determine which of said plurality of individual sensors are to be combined into which of the first and second combinations of sensors.

9. The apparatus of claim 7, further comprising a storage element coupled to said processor, said storage element storing said first and second combined output signals.

10. The apparatus of claim 7, said sensors comprising electromagnetic coils in a parallel MRI imaging apparatus.

11. A parallel imaging apparatus, comprising:
a plurality of individual imaging coils arranged in an array and disposed in space with respect to a field of view of said apparatus;
at least one individual imaging coil being relatively preferentially disposed with respect to a region of interest within said field of view;
at least one individual imaging coil being relatively non-preferentially disposed with respect to a region of interest within said field of view;
a first combined group of imaging coils including said first individual imaging coil, said first combined group being spatially responsive substantially in a first region within said field of view;
a second combined group of imaging coils including said second individual imaging coil, said second combined group being spatially responsive substantially in a second region within said field of view, said second region being greater in spatial extent than said first region; and
a processor receiving a first signal from said first group of imaging coils representative of a combined output of the first combined group of imaging coils and receiving a second signal from said second group of imaging coils representative of a combined output of the second combined group of imaging coils, and providing an output based at least on said first and second signals representative of an image of an object in said region of interest.
